(19) United States
(12) Patent Application Publication
(10) Pub. No.: US 2012/0276711 A1
(43) Pub. Date: Nov. 1, 2012

(54) METHOD FOR MANUFACTURING SEMICONDUCTOR DEVICE HAVING SPACER WITH AIR GAP

(75) Inventors: Hyo Geun YOON, Yongin-si (KR); Ji Yong PARK, Seoul (KR); Sun Jin LEE, Seoul (KR)

(73) Assignee: HYNIX SEMICONDUCTOR INC., Icheon-si (KR)

(21) Appl. No.: 13/244,611

(22) Filed: Sep. 25, 2011

(30) Foreign Application Priority Data
Apr. 27, 2011 (KR) 10-2011-0039818

(51) Int. Cl. H01L 21/76

(52) U.S. Cl. 438/421; 257/E21.573

(57) ABSTRACT

A semiconductor device having a spacer with an air gap is manufactured by forming a first conductive pattern over a semiconductor substrate; forming a spacer on sidewalls of the first conductive pattern; forming a sacrifice layer on sidewall of the spacer, the sacrifice layer having a different etching selectivity with the spacer; forming a second conductive pattern to fill a space between the first conductive pattern and the first conductive pattern; and forming an air gap between the first and second conductive patterns by selectively removing the sacrifice layer.

### CROSS-REFERENCES TO RELATED APPLICATIONS

The present application claims priority to Korean application number 10-2011-0039818, filed on Apr. 27, 2011 which is incorporated by reference in its entirety.

### BACKGROUND

The present invention relates generally to a method for manufacturing a semiconductor device, and more particularly, to a method for manufacturing a semiconductor device having a spacer with an air gap.

With broadening uses of mobile devices and continued miniaturization thereof, the efforts to highly integrate the semiconductor devices continue. In the case of DRAM (Dynamic Random Access Memory), a variety of attempts have been made to form more memory cells in a small area. In general, a DRAM device includes a transistor and a capacitor. The DRAM device has a stacked structure in which the transistor is formed in a semiconductor substrate and the capacitor is formed thereon. In order to electrically connect the transistor and the capacitor, a storage node contact plug is formed between a source area of the transistor and a storage node electrode of the capacitor. Furthermore, a drain region of the transistor is electrically connected to a bit line through a bit line contact plug. When manufacturing a semiconductor memory device, or particularly, a sub-20 nm DRAM device, there are difficulties in securing capacitance of the capacitor due to parasitic capacitance occurring between the bit line and the storage node electrode. Further, if the parasitic capacitance between the bit line and the storage node contact plug increases, a sensing margin of data in the memory cell may decrease. Therefore, technologies for operating even at low capacitance of the capacitor by reducing parasitic capacitance are being developed. However, it is not easy to reduce the parasitic capacitance between the bit line and the storage node contact plug.

### SUMMARY

Embodiments of the present invention are directed to a method for manufacturing a semiconductor device with an air gap, which is capable of operating even at low capacitance by reducing parasitic capacitance between a bit line and a storage node contact plug.

In an embodiment, a method for manufacturing a semiconductor device having a spacer with an air gap includes: forming a first conductive pattern over a semiconductor substrate; forming a spacer on sidewalls of the first conductive pattern; forming a sacrifice layer on sidewall of the spacer, the sacrifice layer having a different etching selectivity with the spacer; forming a second conductive pattern to fill a space between the first conductive pattern and the first conductive pattern; and forming an air gap between the first and second conductive patterns by selectively removing the sacrifice layer.

The method may further include forming a capping layer to seal an upper portion of the air gap, after the forming of the air gap.

The first conductive pattern may include a storage node contact plug, and the second conductive pattern may include a bit line.

The spacer may include nitride.

The sacrifice layer may include a polysilicon or polymer-based organic compound which is formed at temperature of below 500° C.

The sacrifice layer may include a polysilicon or polymer-based organic compound which is formed at temperature of 20 to 40° C.

The sacrifice layer may be formed to a thickness of 30 to 50 Å.

The forming of the second conductive pattern may include: forming a metal layer to fill the space between the first conductive patterns on which the spacer is formed; and recessing the metal layer to form the second conductive layer which partially fills the space between the first conductive patterns.

The sacrifice layer may be removed by supplying a diluted ammonia (DAM) solution obtained by mixing an ammonia (NH₄OH) solution and H₂O at a ratio of 1:5 vol %˜1:30 vol %.

The DAM solution may be supplied at temperature of above 40° C.

The DAM solution may be supplied at temperature of below 70° C.

The DAM solution may be supplied at temperature of 40 to 70° C.

In an embodiment, a method for manufacturing a semiconductor device having a spacer with an air gap includes: forming a first conductive pattern over a semiconductor substrate; forming a first spacer on sidewalls of the first conductive pattern; forming a sacrifice layer on sidewalls of the first spacer, the sacrifice layer having an etching selectivity with the first spacer; forming a second spacer on sidewalls of the sacrifice layer, the second spacer having an etching selectivity with the sacrifice layer; forming a second conductive pattern to fill a space between the first conductive pattern and the first conductive pattern; and forming an air gap between the first and second conductive patterns by removing the sacrifice layer having an etching selectivity with the first and second spacers.

The method may further include forming a silicide metal layer over the semiconductor substrate such that the silicide metal layer is coupled to the second conductive pattern.

### BRIEF DESCRIPTION OF THE DRAWINGS

The above and other aspects, features and other advantages will be more clearly understood from the following detailed description taken in conjunction with the accompanying drawings, in which:

FIG. 1A is a plan view of a semiconductor device which is formed in accordance with an embodiment of the present invention;

FIG. 1B is a cross-sectional view taken along the direction of a line A-A′ of FIG. 1A; and

FIGS. 2 to 13 are diagrams explaining a method for manufacturing a semiconductor device having a spacer with an air gap in accordance with an embodiment of the present invention.

### DESCRIPTION OF SPECIFIC EMBODIMENTS

Hereinafter, exemplary embodiments of the present invention will be described in detail with reference to the accompanying drawings.

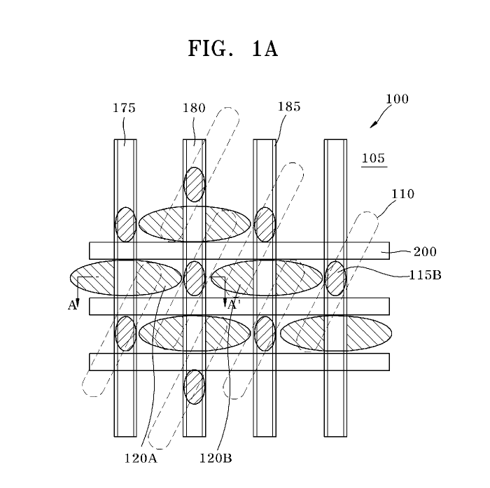

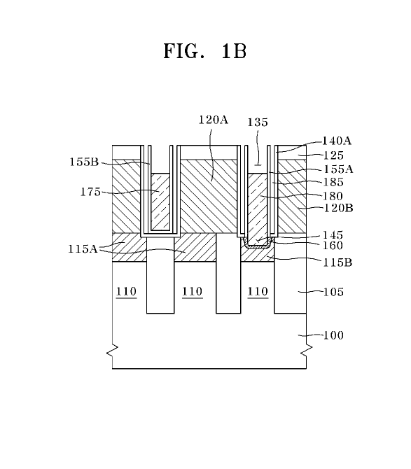

FIG. 1A is a plan view of a semiconductor device which is formed in accordance with an embodiment of the present invention. FIG. 1B is a cross-sectional view taken along the direction of a line A-A′ of FIG. 1A.

Referring to FIGS. 1A and 1B, an isolation layer 105 defining an active region 110 is formed in a semiconductor substrate 100. On the active region 110, first and second landing plugs 115A and 115B are formed. Here, storage node contact plugs 120A and 120B are formed over the first landing plug 115A, and bit lines 175 and 180 are formed over the second landing plug 115B. The bit lines 175 and 180 are arranged in such a line shape as to cross a buried gate 200. The storage node contact plugs 120A and 120B are isolated from each other by the bit line 175 or 180. Each of the bit lines 175 and 180 is buried between the storage node contact plugs 120A and 120B. Therefore, the bit lines 175 and 180 may be called as buried bit lines. A capping layer 190 and a bit line hard mask layer 195 are formed over the bit lines 175 and 180. The capping layer 190 and the bit line hard mask layer 195 may be formed of nitride. A second spacer layer 155A or 155B is formed on the sidewalls and bottom of one of the bit lines 175 and 180, which passes through the isolation layer 105, and a first spacer layer 140A is formed on the sidewalls of the bit line coupled with the second landing plug 115B. Furthermore, a silicide metal layer 160 is formed between the second landing plug 115B and the bit line 175 or 180. Furthermore, the first spacer layer 140A, an air gap 185, and the second spacer layer 155A or 155B are formed between the bit line 175 or 180 and the storage node contact plugs 120A and 120B. The first and second spacer layers may be formed of nitride. A damascene mask 125 is formed on the storage node contact plugs 120A and 120B.

In accordance with the above-described semiconductor device, the spacer structure including the air gap 185 is formed between the storage node contact plugs 120A and 120B and the first or second bit line 175 or 180, thereby reducing parasitic capacitance between the storage node contact plugs and the bit line.

Hereinafter, an embodiment for forming the semiconductor device of FIG. 1 will be described with reference to the drawings.

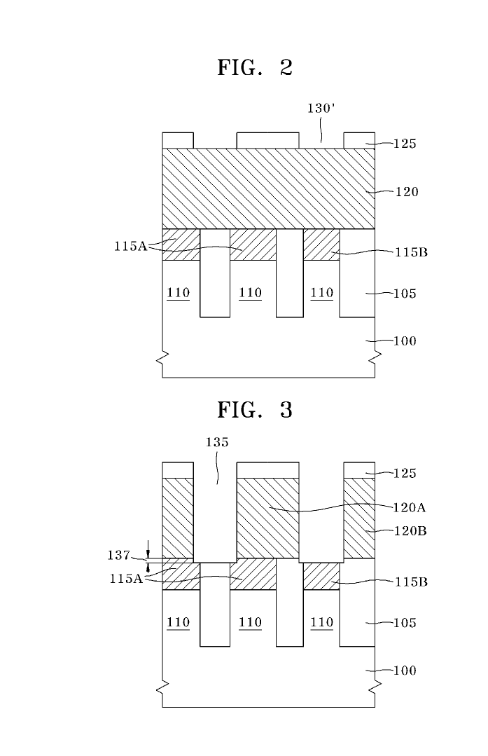

FIGS. 2 to 13 are diagrams explaining a method for manufacturing a semiconductor device having a spacer with an air gap in accordance with an embodiment of the present invention.

Referring to FIG. 2, an isolation layer 105 is formed on a semiconductor substrate 100. An active region 110 is isolated from another active regions by the isolation layer 105 formed on the semiconductor substrate 100. Although not illustrated in FIG. 2, a process of forming a buried gate (refer to reference numeral 200 of FIG. 1A) within the semiconductor substrate 100 may be performed. Then, landing plugs are formed on the surface of the active region 110. The landing plugs include a first landing plug 115A to be coupled to a storage node contact plug which is to be subsequently formed, and a second landing plug 115B to be coupled to a bit line. The first and second landing plugs 115A and 115B may be formed before the isolation layer 105 is formed. For example, a first conductive layer is formed on the semiconductor substrate 100, and then selectively etched to form the first and second landing plugs 115A and 115B. The first conductive layer may be formed of a polysilicon layer. Then, using the first and second landing plugs 115A and 115B as an etch mask, exposed portions of the semiconductor substrate 100 are etched to form isolation trenches, and the isolation trenches are filled with an insulation material to form the isolation layer 105.

A second conductive layer 120 is formed, for example, over the entire surface of the semiconductor substrate 100 including the first and second landing plugs 115A and 115B. The second conductive layer 120 may be formed of a polysilicon layer. Continuously, a damascene mask 125 is formed on the second conductive layer 120. The damascene mask 125 includes an opening 130′ which partially exposes the surface of the second conductive layer 120. A portion exposed by the opening 130′ of the damascene mask 125 corresponds to a region in which a bit line is to be subsequently formed. The damascene mask 125 may be formed of nitride, and have a thickness of 600 to 800 Å.

Referring to FIG. 3, the exposed portion of the second conductive layer 120 is etched by using the damascene mask 125 as an etch mask to form storage node contact plugs 120A and 120B. Bit-line trenches 135 which are formed, for example, between the storage node contact plugs 120A and 120B, and expose the surfaces of the isolation layer 105 and the second landing plugs 115B. In this case, while the etching process for forming the storage node contact plugs 120A and 120B is performed, the exposed portion of the second conductive layer 120 may be further etched by a first thickness 137 from the surfaces of the isolation layer 105 and the second landing plug 115B.

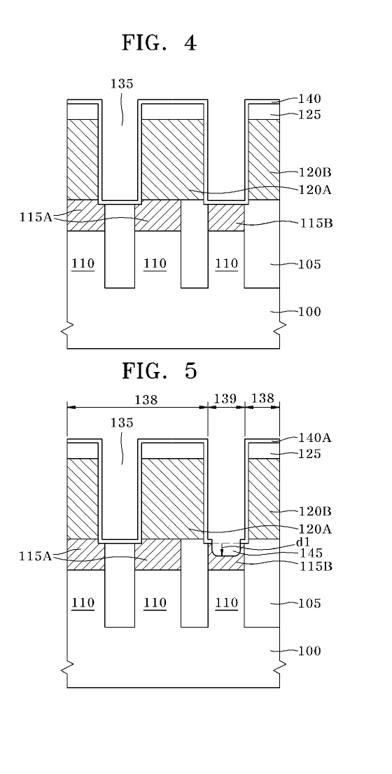

Referring to FIG. 4, a spacer material layer 140 is formed, for example, on the entire surface of the semiconductor substrate 100 including the sidewalls of the storage node contact plugs 120A and 120B. The spacer material layer 140 is formed on the sidewalls of the storage node contact plugs 120A and 120B, the exposed surfaces of the isolation layer 105 and the second landing plug 115B, and the exposed surface of the damascene mask 125 by a deposition method. The spacer material layer 140 may be formed of a nitride layer and has a thickness of 20 to 50 Å.

Referring to FIG. 5, the surface of the second landing plug 115B is selectively exposed. Although not illustrated in FIG. 5, a first bit line contact mask is formed to selectively expose only the bit-line trench 135 in which the second landing plug 115B is formed. The first bit line contact mask may be formed of a photoresist layer. The first bit line contact mask selectively exposes a second region 139 including the second landing plug 115B, while blocking a first region 138 including the first landing plug 115A and the isolation layer 105. Then, the exposed spacer material layer (refer to reference numeral 140 of FIG. 4) of the second region 139 is etched to expose the surface of the second landing plug 115B. The exposed portion of the second landing plug 115B is recessed to form a groove 145 having a first depth d1 within the second landing plug 115B. The first region 138 is not influenced by the etching, because the first region 138 is blocked by the first bit line contact mask. Next, the first bit line contact mask is removed. Then, the spacer material layer 140 becomes a first spacer layer 140A remaining on the sidewalls of the storage node contact plugs 120A and 120B, the isolation layer 105, and the damascene mask 125 of the first region 138.

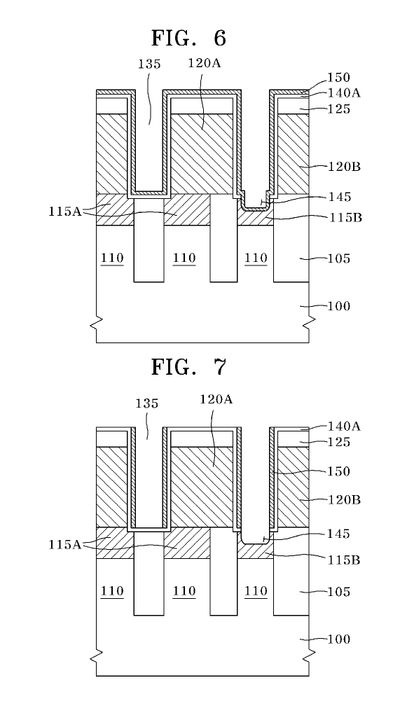

Referring to FIG. 6, a sacrifice layer 150 is formed on the entire surface of the semiconductor substrate 100. The sacrifice layer 150 may be formed by using a polysilicon or polymer-based organic compound. The sacrifice layer 150 is formed along the surface shape of the groove 145 formed in the second landing plug 115B. The sacrifice layer 150 is formed on the first spacer layer 140A and the surface of the groove 145 formed in the second landing plug 115B. In this case, the sacrifice layer 150 may be formed by a low-temperature deposition method. The sacrifice layer 150 may be formed at low temperature of below 500° C. Desirably, the sacrifice layer 150 may be formed at low temperature of 20 to 40° C.

When the sacrifice layer 150 is formed at low temperature of 20 to 40° C., the sacrifice layer 150 is formed in an amorphous state in the case of polysilicon, and may have a thickness of below 50 Å. According to an example, the sacrifice layer 150 is formed to a thickness of 30 to 50 Å. When the sacrifice layer 150 is thinly deposited at a thickness of below 30 Å, the sacrifice layer 150 may be damaged during a recess process using a chemical solution, and even the first spacer layer 140A may be damaged to cause a tunneling effect. In this case, a fail may occur in the storage node contact plugs 120A and 120B. Accordingly, the sacrifice layer 150 may be formed to a thickness of above 30 Å. Furthermore, when the sacrifice layer 150 is formed to a thickness of above 50 Å, the width of the bit-line trench 135 may decrease. In this case, a space in which a bit line conductive layer is to be formed is narrowed, which may make it difficult to bury the bit line conductive layer to the bottom surface.

Accordingly, the sacrifice layer 150 may be formed to a thickness of 30 to 50 Å. For this structure, the sacrifice layer 150 is formed at low temperature of below 500° C. When the sacrifice layer 150 is formed at high temperature of above 500° C., the growth speed of polysilicon may increase, and thus the sacrifice layer 150 may be formed to a thickness of above 50 Å. Furthermore, when the formation process of the polysilicon is performed at temperature of above 500° C., the polysilicon is formed in a crystalline state. When the polysilicon is formed in a crystalline state, a difference in etching characteristics may occur depending on the crystal direction of the polysilicon in a subsequent recess process for selectively removing the sacrifice layer. In this case, it may be difficult to uniformly recess the sacrifice layer. Accordingly, the polysilicon may be formed in an amorphous state at low temperature of below 500° C.

Referring to FIG. 7, an etch back process is performed in such a manner that the sacrifice layer 150 remains on the sidewalls of the storage node contact plugs 120A and 120B. The etch back process is performed by supplying a wet etching solution without a mask. Then, the sacrifice layer 150 which covers the upper surface of the first spacer layer 140A and the bottom surface of the bit-line trench 135 is removed according to etching characteristics in which the etching speed in the vertical direction is higher than that in the side-to-side direction. Accordingly, the sacrifice layer 150 remains in the form of a spacer on the sidewalls of the storage node contact plugs 120A and 120B, and the groove 145 including the surface of the second landing plug 115B is exposed. Here, an etching solution for selectively etching polysilicon is supplied as the wet etching solution.

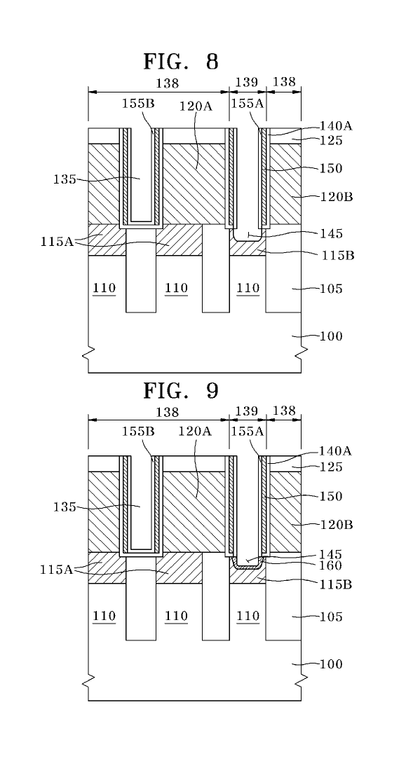

Referring to FIG. 8, second spacer layers 155A and 155B are formed on the sidewalls of the sacrifice layer 150 formed in a spacer shape. The second spacer layers 155A and 155B may be formed of nitride. According to an example, a spacer material layer is formed over the semiconductor substrate 100 having the sacrifice layer 150 formed thereon. Then, a spacer etching process is performed to form the second spacer layers 155A and 155B on the sidewalls of the sacrifice layer 150. The second spacer layers 155A and 155B are formed to a thickness of 20 to 70 Å. Although not illustrated in FIG. 8, a second bit line contact mask is formed to selectively expose the second region 139 in which the second landing plug 115B is formed, during the spacer etching process. The second bit line contact mask may be formed of a photoresist layer. The second bit line contact mask selectively exposes the second region 139 while blocking the first region 138. Then, when the spacer etching process using the second bit line contact mask is performed, the second spacer layer 155B formed in the first region 138 remains to a predetermined thickness on the bottom, because the first spacer layer 140A remains under the second spacer layer 155B. However, the bottom surface of the second spacer layer 155A of the second region 139 is etched to expose the surface of the second landing plug 115B. Accordingly, the second spacer layer 155A of the second region 139 is formed in such a shape as to surround the sacrifice layer 150. The second bit line contact mask is removed.

Referring to FIG. 9, a silicide metal layer 160 is formed on the exposed second landing plug 115B of the second region 139. According to an example, a metal layer having a stacked structure of titanium (Ti) and titanium nitride (TiN) is formed over the semiconductor substrate 100. The metal layer may be formed to a thickness of 30 to 100 Å. Then, a heat treatment process may be formed on the semiconductor substrate 100 having the metal layer formed thereon. As the heat treatment process, an annealing process may be performed. When the annealing process is performed, a silicide reaction occurs between the second landing plug 115B and the metal layer having a stacked structure of Ti and TiN which is in direct contact with the surface of the second landing plug 115B including polysilicon, and thus the silicide metal layer 160 is formed. The silicide metal layer 160 includes titanium silicide (TiSix).

After the silicide metal layer 160 is formed, a cleaning process is performed to remove Ti and TiN which was not subjected to the silicide reaction. The cleaning process may be performed by using a sulfuric acid peroxide mixture (SPM) solution, an ammonia (NH₄OH) solution, or a standard clean-1 (SC-1) solution obtained by mixing H₂O₂ and H₂O. Through the cleaning process, Ti and TiN are removed, and the silicide metal layer 160 remains on the bottom surface of the second region 138, as illustrated in FIG. 9.

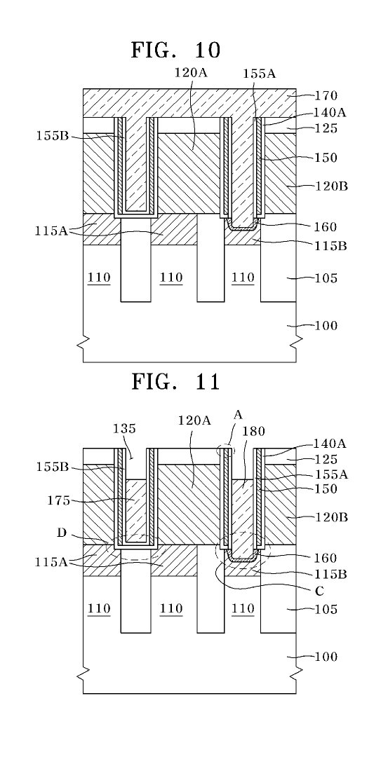

Referring to FIG. 10, a bit line conductive layer 170 is formed over the semiconductor substrate 100. The bit line conductive layer 170 may be formed of tungsten (W). The bit line conductive layer 170 is formed to such a thickness as to completely fill the bit-line trenches (refer to reference numeral 135 of FIG. 9).

Referring to FIG. 11, the bit line conductive layer (refer to reference numeral 170 of FIG. 10) is recessed to form first and second bit lines 175 and 180 which partially fill the bit-line trenches 135. According to an example, a planarization process is performed on the semiconductor substrate 100 having the bit line conductive layer 170 formed thereon. The planarization process may be performed by polishing the surface of the bit line conductive layer 170, in order to recess the bit line conductive layer 170 to a uniform thickness. The planarization process may be performed by a chemical mechanical polishing (CMP) process. The bit line conductive layer 170 of which the surface was polished by the planarization process is recessed to a predetermined depth from the surface to form the first and second bit lines 175 and 180. At a portion C which is in contact with the silicide metal layer 160 of the second bit line 180, the bit line conductive layer is buried to the depth of the groove 145 formed in the landing plug 115B. Therefore, the vertical length of the second bit line 180 becomes larger than that of the first bit line 175 having a portion D passing through the second isolation layer 105. In this case, the recess process may be performed by an etch back process. Through the recess process, a portion ‘A’ including the surface of the sacrifice layer 150 at an upper portion of the bit-line trench 135 is exposed.

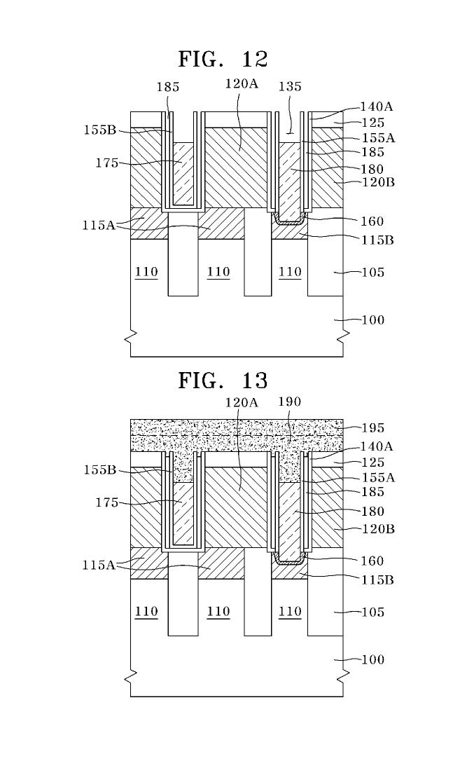

Referring to FIG. 12, the sacrifice layer (refer to reference numeral 150 of FIG. 11) is selectively recessed and removed. Accordingly, an air gap 185 is formed between the storage node contact plugs 120A and 120B and the first or second bit line 175 or 180. The sacrifice layer 150 may be removed through a wet etching method. The wet etching method for removing the sacrifice layer 150 may be performed by supplying a high-temperature diluted ammonia (DAM) solution. For this operation, a DAM solution obtained by mixing NH₄OH solution and H₂O at a ratio of 1:5 vol %˜1:30 vol % is formed, and supplied at high temperature of 40 to 70° C. to perform the wet etching process. When the DAM solution is supplied at temperature of below 40° C., the sacrifice layer 150 is not recessed. Therefore, the DAM solution may be supplied at high temperature of above 40° C. Furthermore, when the DAM solution is supplied at temperature of above 70° C., mass productivity may decrease. In this case, it is difficult to control a concentration at which the sacrifice layer 150 may be recessed. Accordingly, the DAM solution may be supplied at temperature of 40 to 70° C., in order to selectively recess and remove the sacrifice layer 150. In this case, since the DAM solution has a lower viscosity than other cleaning solutions, the DAM solution may effectively permeate even through a pattern having a small width during the wet etching process.

As the spacer structure including an air gap, a structure having a metal layer formed between a nitride layer and a nitride layer, and a structure having a metal layer formed between an oxide layer and a nitride layer may be formed. In this case, the SPM solution or SC-1 solution is used to selectively recess and remove the metal layer, in order to form the air gap. The nitride layer, the oxide layer, or the double layer of nitride and oxide serving as an etch barrier for the bit line is formed to a small thickness of 20 to 30 Å. When the etch barrier is formed to a thickness of above 30 Å, the width of the bit-line trench in which the bit line may be buried may decrease, which makes it difficult to completely bury the bit line to the bottom surface. Therefore, the etch barrier is formed at a thickness of below 30 Å. However, when the etch barrier is formed at a thickness of 20 to 30 Å, a loss of nitride may occur during an etching process in which a nitride layer is deposited on the bit line contact plug and the bit-line trench is then formed. When the SPM solution or SC-1 solution is applied to remove the metal layer in a state in which the loss of nitride occurred, the etching solution may permeate through the lost nitride, thereby causing a loss of the bit line.

That is, when the structure having the metal layer formed between the oxide layer and the nitride layer is formed or the SPM solution or SC-1 solution is used, an etching reaction may occur on the metal. On the other hand, the DAM solution in accordance with an embodiment of the present invention selectively etches only polysilicon, and does not etch the metal. Accordingly, when the sacrifice layer 150 is removed, the first spacer layer 140A, the second spacer layer 155A, the first and second bit lines 175 and 180, and the damascene mask 125 have an etching selectivity with the DAM solution and the sacrifice layer 150 including polysilicon, and thus are not lost. Furthermore, since the storage node contact plugs 120A and 120B are protected by the damascene mask 125, a loss does not occur even during the process of removing the sacrifice layer 150. Accordingly, it is possible to stably remove the sacrifice layer 150 while having no effect upon the other layers.

Referring to FIG. 13, a capping layer 190 is formed on the first and second bit lines 175 and 180, the first spacer layer 140A, and the second spacer layer 155A. The capping layer 190 serves to substantially prevent the first and second bit lines 175 and 180 from being lifted by the air gap 185 or substantially prevent the air gap 185 from being damaged during a subsequent contact hole etching process for forming a storage node. The capping layer 190 may be formed of another insulation material having a different etching selectivity with the first and second bit lines 175 and 180. The capping layer 190 may include nitride formed at low temperature. The capping layer 190 is formed at such a thickness as to completely fill the rest portion of the bit-line trenches (135 of FIG. 12) in which the first and second bit lines 175 and 180 are partially buried. Accordingly, as the capping layer 190 is formed even on the air gap 185, the capping layer 190 fills a portion of the air gap 185 which corresponds to a depth of 100 to 500 Å from the upper portion of the air gap 185, thereby sealing the air gap 185. Then, a bit line hard mask layer 195 is used to form a nitride layer on the capping layer 190. The nitride layer may be polished to planarize the surface of the bit line hard mask layer 195. The surface of the bit line hard mask layer 195 may be polished by a CMP process.

In accordance with an embodiment of the present invention, the first spacer layer 140A, the air gap 185, and the second spacer layer 140B are sequentially arranged between the storage node contact plugs 120A and 120B and the first or second bit line 175 or 180. As such, the air gap 185 is formed between the storage node contact plugs 120A and 120B and the first or second bit line 175 or 180, thereby reducing a dielectric constant. Therefore, it is possible to reduce parasitic capacitance between the storage node contact plugs 120A and 120B and the first or second bit line 175 or 180.

In accordance with an embodiment of the present invention, the spacer structure having the air gap between the bit line and the storage node contact plug is introduced to reduce parasitic capacitance by using a low dielectric constant of the air gap. Furthermore, during the wet etching process for forming the air gap, an etching solution which has no effect upon the metal layer is introduced to stably form the air gap.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A method for manufacturing a semiconductor device having a spacer with an air gap, comprising:
forming a first conductive pattern over a semiconductor substrate;
forming a spacer on sidewalls of the first conductive pattern;
forming a sacrifice layer on sidewall of the spacer, wherein the sacrifice layer has a different etching selectivity with the spacer;
forming a second conductive pattern to fill a space between the first conductive pattern and the first conductive pattern; and
forming an air gap between the first and second conductive patterns by selectively removing the sacrifice layer.

2. The method of claim 1, further comprising:
forming a capping layer to seal an upper portion of the air gap, after the forming of the air gap.

3. The method of claim 1, wherein the first conductive pattern comprises a storage node contact plug, and the second conductive pattern comprises a bit line.

4. The method of claim 1, wherein the spacer comprises nitride.

5. The method of claim 1, wherein the sacrifice layer comprises a polysilicon or polymer-based organic compound which is formed at temperature of below 500° C.

6. The method of claim 1, wherein the sacrifice layer comprises a polysilicon or polymer-based organic compound which is formed at temperature of 20 to 40° C.

7. The method of claim 1, wherein the sacrifice layer is formed to a thickness of 30 to 50 Å.

8. The method of claim 1, wherein the forming of the second conductive pattern comprises:
forming a metal layer to fill the space between the first conductive patterns on which the spacer is formed; and
recessing the metal layer to form the second conductive layer which partially fills the space between the first conductive patterns.

9. The method of claim 1, wherein the sacrifice layer is removed by supplying a diluted ammonia (DAM) solution obtained by mixing an ammonia (NH₄OH) solution and H₂O at a ratio of 1:5 vol % to 1:30 vol %.

10. The method of claim 9, wherein the DAM solution is supplied at temperature of above 40° C.

11. The method of claim 9, wherein the DAM solution is supplied at temperature of below 70° C.

12. The method of claim 9, wherein the DAM solution is supplied at temperature of 40 to 70° C.

13. A method for manufacturing a semiconductor device having a spacer with an air gap, comprising:
forming a first conductive pattern over a semiconductor substrate;
forming a first spacer on sidewalls of the first conductive pattern;
forming a sacrifice layer on sidewalls of the first spacer, wherein the sacrifice layer has an etching selectivity with the first spacer;
forming a second spacer on sidewalls of the sacrifice layer, wherein the second spacer has an etching selectivity with the sacrifice layer;
forming a second conductive pattern to fill a space between the first conductive pattern and the first conductive pattern; and
forming an air gap between the first and second conductive patterns by removing the sacrifice layer having an etching selectivity with the first and second spacers.

14. The method of claim 13, further comprising:
forming a silicide metal layer over the semiconductor substrate such that the silicide metal layer is coupled to the second conductive pattern.

15. The method of claim 13, further comprising:
forming a capping layer to seal an upper portion of the air gap, after the forming of the air gap.

16. The method of claim 13, wherein the first conductive pattern comprises a storage node contact plug, and the second conductive pattern comprises a bit line.

17. The method of claim 13, wherein the first or second spacer comprises nitride.

18. The method of claim 13, wherein the sacrifice layer comprises a polysilicon or polymer-based organic compound which is formed at temperature of below 500° C.

19. The method of claim 13, wherein sacrifice layer comprises a polysilicon or polymer-based organic compound formed at temperature of 20 to 40° C.

20. The method of claim 13, wherein the sacrifice layer is formed to a thickness of 30 to 50 Å.

21. The method of claim 13, wherein the forming of the second conductive pattern comprises:
forming a metal layer to fill the space between the first conductive patterns in which the first spacer, the sacrifice layer, and the second spacer are formed; and
recessing the metal layer to form the second conductive layer which partially fills the space between the first conductive patterns.

22. The method of claim 13, wherein the sacrifice layer is removed by supplying a DAM solution obtained by mixing NH₄OH and H₂O at a ratio of 1:5 vol % to 1:30 vol %.

23. The method of claim 22, wherein the DAM solution is supplied at high temperature of above 40° C.

24. The method of claim 22, wherein the DAM solution is supplied at temperature of below 70° C.

25. The method of claim 22, wherein the DAM solution is supplied at temperature of 40 to 70° C.
